(19) United States
(12) Patent Application Publication
(10) Pub. No.: US 2026/0316576 A1
(43) Pub. Date: Oct. 15, 2026

(54) ADJUSTMENT OF OPERATING PARAMETERS OF A BATTERY-ELECTRIC MACHINE USING THROUGHPUT ESTIMATION

(71) Applicant: Caterpillar Paving Products Inc., Brooklyn Park, MN (US)

(72) Inventors: Ryan J. Nelson, Maple Grove, MN (US); Eric S. Engelmann, Delano, MN (US)

(73) Assignee: Caterpillar Paving Products Inc., Brooklyn Park, MN (US)

(21) Appl. No.: 19/176,443

(22) Filed: Apr. 11, 2025

(51) Int. Cl. B60L 3/00; B60L 1/00; B60L 3/12; B60L 15/20; B60L 58/10; E01C 19/48; E01C 23/088; E01C 23/12; G01R 31/382

(52) U.S. Cl. CPC B60L 3/0023; B60L 1/003; B60L 3/12; B60L 15/20; B60L 58/10; G01R 31/382; B60L 2200/40; B60L 2240/12; B60L 2240/421; B60L 2240/423; B60L 2240/427; B60L 2240/429; B60L 2240/54; B60L 2240/70; B60L 2250/16; E01C 19/48; E01C 23/088; E01C 23/127

(57) ABSTRACT

A control system for a battery-electric machine includes a battery monitoring system for one or more batteries of the battery-electric machine, one or more sensors configured to measure multiple motor operating parameters of an electric motor that operates a throughput-affecting component of the battery-electric machine, and a controller. The controller may be configured to receive, from the battery monitoring system, energy data indicating an energy consumption of the battery-electric machine, receive, from the one or more sensors, sensor data relating to the multiple motor operating parameters, determine, using the sensor data, a throughput estimate for the battery-electric machine, determine, using the energy data and the throughput estimate, whether the battery-electric machine is operating inefficiently, and cause, based on determining that the battery-electric machine is operating inefficiently, an adjustment to a travel speed of the battery-electric machine or a motor speed of the electric motor.

### TECHNICAL FIELD

The present disclosure relates generally to battery-electric machines and, for example, to the adjustment of operating parameters of a battery-electric machine using throughput estimation.

### BACKGROUND

Electrical machinery, such as vehicles or other mobile machinery, which are at least partially powered by on-board batteries, can be an environmentally friendly alternative to machinery running on fossil fuels. These battery electric machines help reduce greenhouse gas emissions and dependency on non-renewable energy sources. However, they also face several challenges, particularly in terms of energy efficiency and operating duration.

One limitation of battery-powered machinery is a restricted operating time due to battery capacity constraints. Unlike diesel-powered machines that can operate for extended periods with refueling, electric machines often require frequent recharging, leading to increased downtime and reduced overall productivity. Additionally, inefficient energy usage, which can be caused by factors such as suboptimal power distribution, mechanical inefficiencies, or excessive energy consumption under certain operating conditions, can further shorten operational periods between charges.

Furthermore, the complexity of electrical machinery introduces challenges in diagnosing performance issues. Variations in energy consumption may not always be immediately apparent, making it difficult to determine whether increased power usage is due to normal fluctuations, environmental conditions, or underlying inefficiencies. The failure to identify and address performance issues may lead to unnecessary power consumption, performance degradation, or premature wear on components.

Korean Patent Application Publication No. 10-2020-0030973 (the '973 application) discloses that a server receiving a torque command value and current information calculates a maximum torque in real time and drives the motor based on the current command value corresponding to the calculated maximum torque. The '973 application does not disclose making an adjustment based on energy data and a throughput estimate to improve energy efficiency.

The control system of the present disclosure solves one or more of the problems set forth above and/or other problems in the art.

### SUMMARY

A control system for a battery-electric machine may include a battery monitoring system for one or more batteries of the battery-electric machine, one or more sensors configured to measure multiple motor operating parameters of an electric motor that operates a throughput-affecting component of the battery-electric machine, and a controller. The controller may be configured to receive, from the battery monitoring system, energy data indicating an energy consumption of the battery-electric machine, receive, from the one or more sensors, sensor data relating to the multiple motor operating parameters. The controller may be configured to determine, using the sensor data, a throughput estimate for the battery-electric machine. The controller may be configured to determine, using the energy data and the throughput estimate, whether the battery-electric machine is operating inefficiently. The controller may be configured to cause, based on determining that the battery-electric machine is operating inefficiently, an adjustment to a travel speed of the battery-electric machine or a motor speed of the electric motor.

A method may include receiving, by a controller, energy data indicating an energy consumption of a battery-electric machine and sensor data relating to multiple motor operating parameters of an electric motor of the battery-electric machine. The method may include determining, by the controller and using the sensor data, a throughput estimate for the battery-electric machine. The method may include determining, by the controller and using the energy data and the throughput estimate, whether the battery-electric machine is operating inefficiently. The method may include and causing, by the controller and based on determining that the battery-electric machine is operating inefficiently, an adjustment to one or more operating parameters of the battery-electric machine.

A battery-electric machine may include a battery monitoring system for one or more batteries of the battery-electric machine, a throughput-affecting component that contributes to a throughput of a work operation of the battery-electric machine, an electric motor configured to operate the throughput-affecting component, a motor inverter configured to control the electric motor, one or more sensors configured to measure one or more operating parameters of the electric motor, and a controller. The controller may be configured to receive, from the battery monitoring system, energy data indicating an energy consumption of the battery-electric machine. The controller may be configured to receive, from the motor inverter and the one or more sensors, sensor data relating to multiple motor operating parameters of the electric motor. The controller may be configured to determine, using the sensor data, a throughput estimate for the battery-electric machine. The controller may be configured to determine, using the energy data and the throughput estimate, an efficiency metric indicative of whether the battery-electric machine is operating inefficiently. The controller may be configured to cause, based on the efficiency metric, an adjustment to a travel speed of the battery-electric machine or a motor speed of the electric motor.

### BRIEF DESCRIPTION OF THE DRAWINGS

FIG. 1 is a side elevational view of an example machine.

FIG. 2 is a diagram of an example of a control system.

FIG. 3 is a flowchart of an example method.

### DETAILED DESCRIPTION

This disclosure relates to a control system, which is applicable to any battery-electric machine. For example, the machine may be a paving machine, a compactor machine, a cold planer, a grading machine, a backhoe loader, a wheel loader, a harvester, an excavator, a motor grader, a skid steer loader, a tractor, a dozer, a vehicle, or the like.

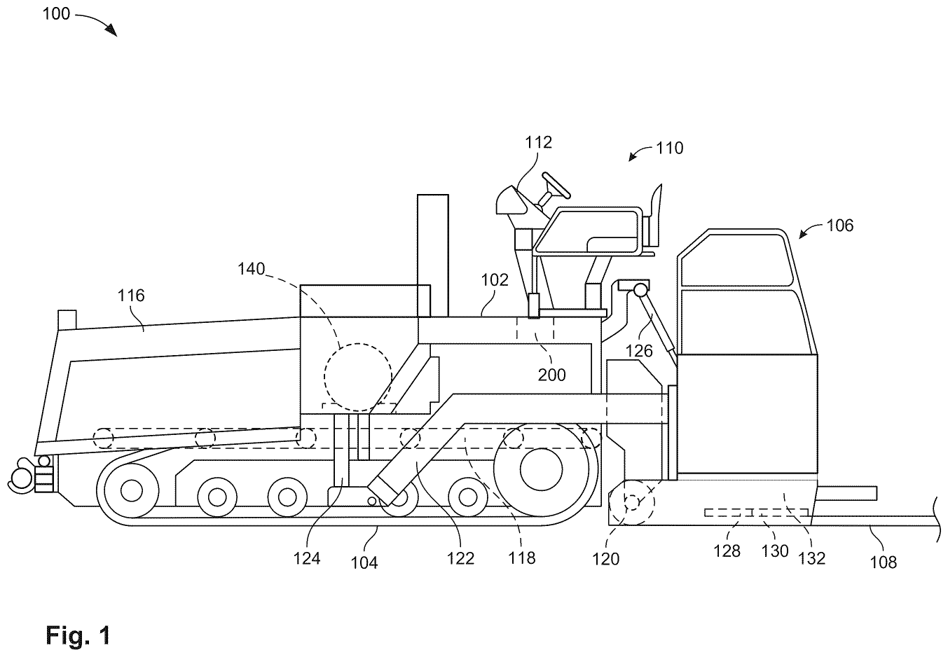

FIG. 1 is a side elevational view of an example machine 100. FIG. 1 shows an example where the machine 100 is a paving machine. However, the machine 100 may be another type of machine, as described above. The machine 100 may be a battery-electric machine (e.g., that uses electrical power stored in one or more batteries for propulsion and/or operation of the machine 100).

The machine 100 includes a frame 102 with a set of ground-engaging elements 104 such as tracks or wheels coupled with the frame 102. The ground-engaging elements 104 may be driven by an electric powertrain system 140. Additionally, or alternatively, the electric powertrain system 140 may drive or power another component or system of the machine 100, such as one or more pumps (e.g., of a hydraulic power system of the machine 100) and/or other components described herein. The electric powertrain system 140 may include one or more batteries (e.g., a battery pack) and one or more electric motors.

A screed 106 can be positioned at the rear end of the machine 100 to spread and compact paving material into a mat 108 having a desired thickness, size, uniformity, crown profile, and cross slope. The machine 100 also includes an operator station 110 having a seat and a console, which includes various controls for directing operations of the machine 100 by inputting instructions at an input panel 112.

The machine 100 further includes a hopper 116 for storing a paving material, and a conveyor system including one or more conveyors 118 configured to move paving material from the hopper 116 to the screed 106 at the rear of the machine 100. One or more augers 120 are arranged near the forward end of the screed 106 to receive the paving material supplied by the conveyor 118 and spread the material evenly beneath the screed 106. The screed 106 can be pivotally coupled behind the machine 100 by one or more tow arms 122 that extend between the frame 102 of the paving machine and the screed 106. Alternatively, the screed 106 can be pivotally coupled behind the machine 100 by a pair of tow arms 122 that extend between a tow point on the frame 102 of the machine 100 and the screed 106.

The tow arms 122 can also have the tow point raised and lowered on the machine 100 using a positioning cylinder 124 which, when moved up and down, moves the tow point of the tow arms 122 and changes an angle of attack of the screed 106. Also, as part of a paving process, one or more cylinders 126 on the screed 106 can raise or lower portions of the screed 106. For example, to change a height or paving angle of a main screed plate 128, the machine 100 may use one or more extender screed plates 130. The screed 106 can include a screed frame 132 with the main screed plate 128 coupled to the screed frame 132. The screed plate 128 is configured to float on the paving material of the mat 108 laid upon a prepared paving bed and to “smooth” or level and compact the paving material on the base surface, such as for example a roadway or roadbed. The screed 106 can further include the one or more extender screed plates 130 that extend beyond the main screed plate 128 to extend the paving width of the screed 106.

The machine 100 further includes a control system 200. As described herein, the control system 200 may be configured to make an adjustment based on energy data and a throughput estimate to improve energy efficiency of the machine 100.

As indicated above, FIG. 1 is provided as an example. Other examples may differ from what is described with regard to FIG. 1.

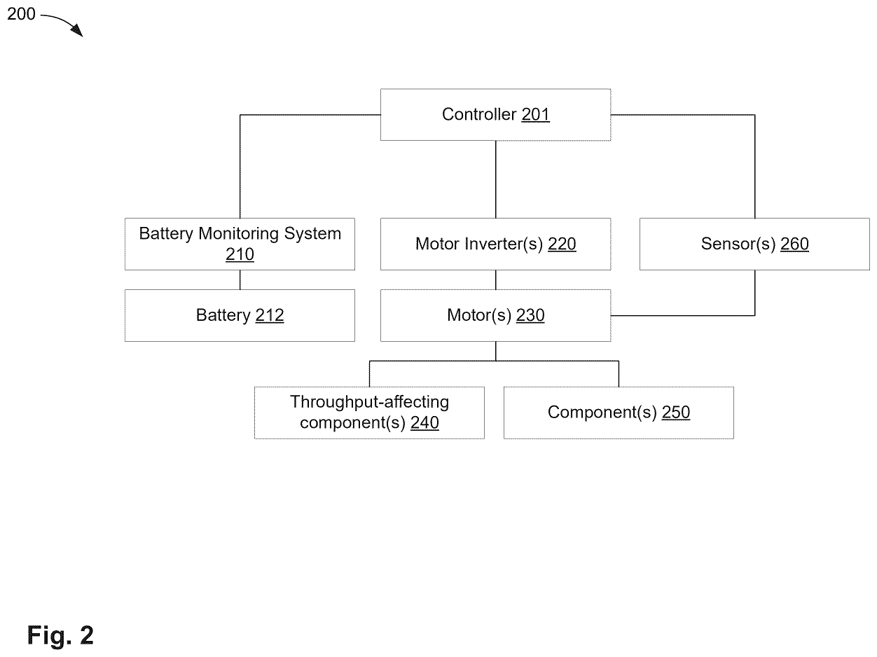

FIG. 2 is a diagram of an example of the control system 200. The control system 200 includes a controller 201, a battery monitoring system (BMS) 210, one or more batteries 212, one or more motor inverters 220, one or more motors 230, one or more throughput-affecting components 240, one or more components 250, and one or more sensors 260.

The controller 201 is provided for electrically controlling various aspects of the machine 100. For example, the controller 201 can send and receive signals from various components of the machine 100 during the operation of the machine 100. The controller 201 may include one or more memories and one or more processors communicatively coupled to the one or more memories. A processor may include a central processing unit, a graphics processing unit, a microprocessor, a controller, a microcontroller, a digital signal processor, a field-programmable gate array, an application-specific integrated circuit, and/or another type of processing component. The processor may be implemented in hardware, firmware, or a combination of hardware and software. The processor may be capable of being programmed to perform one or more operations or processes described elsewhere herein. A memory may include volatile and/or nonvolatile memory. For example, the memory may include random access memory (RAM), read only memory (ROM), a hard disk drive, and/or another type of memory (e.g., a flash memory, a magnetic memory, and/or an optical memory). The memory may be a non-transitory computer-readable medium. The memory may store information, one or more instructions, and/or software (e.g., one or more software applications) related to the operation of the controller 201. The controller 201 may be configured to perform one or more operations described herein.

The battery 212 may be any energy storage device configured to supply electrical power for operation of various components of the machine 100. For example, the battery 212 can be configured to provide energy to the motor 230 for operating the throughput-affecting component 240 and/or the component 250. The battery 212 may include one or more batteries, such as one or more lithium-ion (Li-ion) batteries, lithium-ion polymer batteries, nickel-metal hydride (NiMH) batteries, lead-acid batteries, nickel cadmium (Ni—Cd) batteries, zinc-air batteries, sodium-nickel chloride batteries, or other types of batteries. In some implementations, multiple battery cells may be grouped together, in series or in parallel, within a battery module. Multiple battery modules may be grouped together, such as in series, within a battery string. One or more battery strings may be provided within a battery pack, such as a group of battery strings linked together in parallel. Accordingly, the battery 212 may include one or more battery packs, one or more battery strings, one or more battery modules, and/or one or more battery cells. The battery 212 can be operatively coupled with the BMS 210.

The BMS 210 may be a hardware and/or software component configured to monitor the battery 212 of the machine 100. For example, the BMS 210 can be configured to monitor and control operating parameters of the battery 212, such as a voltage, a current, a temperature, a state of charge (SOC), a state of health (SOH), a state of power (SOP), etc. The BMS 210 may include and/or be operatively coupled with the sensor 260 to monitor the battery 212. The BMS 210 can be configured to communicate with the controller 201 to provide the operating parameters of the battery 212. In some embodiments, the BMS 210 can be configured to control energy distribution among the motor 230, the throughput-affecting component 240, the component 250, etc., thereby ensuring efficient and reliable operation of the machine 100.

The motor 230 may be an electric motor configured to convert electrical energy from the battery 212 into power for operating various elements of the machine 100. The motor 230 can be configured to provide a torque for operation of the throughput-affecting component 240 and/or the component 250. The motor 230 may include one or more first motors configured to operate the throughput-affecting component 240, and/or one or more second motors configured to operate the component 250. For example, each of the one or more first motors may be configured to drive a corresponding one of the throughput-affecting components 240, and each of the one or more second motors may be configured to drive a corresponding one of the components 250. The motor 230 may be operatively coupled to the throughput-affecting component 240 and/or the component 250. The motor 230 can be controlled by the controller 201 and/or the motor inverter 220 (e.g., a variable frequency drive (VFD)) may be configured to control the motor 230. The controller 201 and/or the motor inverter can be configured to control and regulate a power flow from the battery 212. For example, the controller 201 and/or the motor inverter can be configured to adjust motor parameters (e.g., a speed, a torque, a rotation direction, etc.) of the motor 230.

The throughput-affecting component 240 may include one or more elements of the machine 100 that contribute to a throughput of a work operation of the machine 100. In the context of work operations, “throughput” may refer to a rate at which a system or process of the machine 100 produces output, such as a rate of material processing, Thus, the throughput-affecting component 240 may be a component of the machine 100 that can affect the rate at which a system or process of the machine 100 produces output. For example, the throughput-affecting component 240 may be or include an auger (e.g., auger 120), a conveyor (e.g., conveyor 118), a milling drum, or any other material-handling or processing device. For example, in a paving machine, an auger may be used to distribute paving material, while a conveyor may transport material from a hopper to a screed, and therefore both the auger and the conveyor affect the throughput of the paving machine. As another example, in a cold planer, a milling drum may be used to grind and remove road surfaces, while a conveyor may transport the milled material away, and therefore both the milling drum and the conveyor affect the throughput of the cold planer. The throughput-affecting component 240 can be driven by the motor 230, which in turn may be controlled by the battery 212, the controller 201, and/or the motor inverter 220.

The component 250 may include one or more elements of the machine 100 that contribute to the overall operation and/or functionality of the machine 100 (e.g., other than the throughput-affecting component 240). In some embodiments, the component 250 may be an element of the machine 100 that does not directly contribute to the throughput of the work operation of the machine 100. For example, the component 250 may include a pump, a track system, a steering mechanism, or other supporting subsystems for machine movement, control, or auxiliary functions. The component 250 may be powered by the motor 230 and receive electrical energy from the battery 212, either directly or through additional control systems such as the motor inverter 220. While the component 250 may not directly influence the throughput of the machine 100, the component 250 can be controlled to optimize the energy efficiency and/or throughput of the machine 100. In some embodiments, the sensor 260 may be operatively coupled with the component 250. Although shown as connected to the motor 230 along with the throughput-affecting component 240, the component 250 may be operatively coupled to a separate motor system (e.g., an electric motor, a motor inverter, etc.), in some embodiments.

The sensor 260 may be one or more sensing devices configured to detect parameters of various elements of the machine 100 and provide sensor data. The sensor 260 may be coupled to or included in various elements of the control system 200, such as the BMS 210, the battery 212, the motor 230, the motor inverter 220, the throughput-affecting component 240, the component 250, etc. For example, a sensor 260 may be configured to detect and/or measure battery-related parameters such as a voltage, a current, a temperature, an SOC, and/or an SOH. In some examples, a sensor 260 may be configured to detect and/or measure electrical parameters of the motor inverter 220, such as input/output voltages, a current, power faults (e.g., overvoltage, overcurrent, overheating, etc.), or the like. In some examples, a sensor 260 may be configured to detect and/or measure operating parameters of the motor 230. For example, the operating parameters of the motor 230 may include a current, a voltage, a speed of the motor 230, etc. In some examples, a sensor 260 may be configured to detect and/or measure operating parameters of the throughput-affecting component 240. For example, the sensor 260 can be configured to monitor a machine travel speed, an electric motor speed, a hydraulic pump speed, a pad thickness setting, a cut depth setting, a material flow rate, etc. In some examples, a sensor 260 may be configured to detect and/or measure operating parameters of the component 250. For example, the sensor 260 may be configured to monitor a hydraulic pressure, a track position and/or speed, a steering angle and/or force, etc. The sensor data collected by the sensor 260 may be processed (e.g., by the controller 201), as described herein, to adjust operating parameters of the machine 100, improving the efficiency and performance of the machine 100.

During operation of the machine 100, or at another time, the controller 201 may receive, from the BMS 210, energy data. The energy data may indicate an energy consumption of the machine 100. The energy data may include a current value, a voltage value, and/or a total energy value over a given time period. Additionally, or alternatively, the energy data may include energy consumption data for the throughput-affecting component 240 and/or the component 250. Additionally, or alternatively, the energy data may include a discharging rate, a battery discharge amount, etc. of the battery 212.

The controller 201 may receive, from the sensor 260, the sensor data. The sensor data may relate to the operating parameters (e.g., a current, a voltage, a speed of the motor, etc.) of the motor 230. For example, the controller 201 may receive the sensor data from a sensor 260 coupled to the motor 230 and/or the motor inverter 220 that operate the throughput-affecting component 240, and/or from a sensor 260 coupled to the motor 230 and/or the motor inverter 220 that operate the component 250. In some embodiments, the motor 230 may be a single motor configured to operate the throughput-affecting component 240 and the component 250, and the control system 200 may include a distribution unit (not shown) that distributes between components (e.g., the throughput-affecting component 240, the component 250, etc.). The controller 201 can be configured to receive, from the sensor 260 that is coupled to the distribution unit, the sensor data indicating the operating parameters associated with the throughput-affecting component 240 and/or the component 250. In some embodiments, the controller 201 may transmit the energy data and/or the sensor data to a remotely-located system for fleet-level efficiency monitoring.

The controller 201 may determine, using the sensor data, a throughput estimate for the machine 100. The throughput estimate may indicate an amount of material being processed, transported, or manipulated by the throughput-affecting component 240 over a given time period. For example, the controller 201 may determine the throughput estimate over the same time period over which the energy data are collected. In some embodiments, the controller 201 may determine the throughput estimate based on a voltage, a current, and/or a speed of the motor 230 (e.g., which the controller 201 may use to determine a torque or a power of the motor 230 and/or a speed of the throughput-affecting component 240). For example, the controller 201 may determine the throughput estimate based on a speed of the motor 230 and at least one of a torque, a power, or a load of the motor 230 (e.g., because speed alone may not provide an accurate estimate of throughput). For example, in a paving machine, an auger motor speed and an auger motor torque, power, and/or load can be used to estimate the throughput (e.g., an amount of material being processed). When the machine 100 includes a conveyor as the throughput-affecting component 240, the controller 201 can determine the throughput estimate based on a conveyor motor speed and a conveyor motor torque, power, and/or load. In a cold planer and/or a milling machine, the controller 201 may use a drum motor speed, a drum cut depth, and a drum motor torque, power, and/or load, to estimate the throughput (e.g., an amount of material being processed).

The controller 201 may determine, using the energy data and the throughput estimate, whether the machine 100 is operating inefficiently. The controller 201 can determine an efficiency of the machine 100 based on the energy data from the BMS 210 and the throughput estimate obtained based on the sensor data. In some embodiments, the controller 201 may determine an efficiency metric based on the energy data and the throughput estimate, and determine whether the efficiency metric satisfies an efficiency threshold. The efficiency metric may be a ratio of the throughput to an expected throughput for the given energy consumption or a ratio of the throughput to the energy consumption, among other examples. In response to the energy metric satisfying the threshold (e.g., being less than the threshold), the controller 201 can determine that the machine 100 is operating inefficiently. In some embodiments, the controller 201 may determine whether the machine 100 is operating inefficiently based on a machine learning (ML) model trained to output an efficiency indication based on an input of the energy data, the sensor data, and/or the throughput estimate.

For example, in a paver, the controller 201 may determine the efficiency metric by comparing the throughput estimate to an expected throughput based on the energy consumption of the auger and/or conveyor motors. In response to the auger and/or conveyor motors consuming an amount of power higher than a power threshold but processing less material than expected, the efficiency metric may satisfy the efficiency threshold, indicating inefficient operation. In a cold planer and/or a milling machine, the efficiency metric may be based on a volume of material processed per unit of energy consumed by the milling drum motor. If the energy consumption is higher than an energy threshold but the estimated milled material amount is lower than expected, the controller 201 may determine that the efficiency metric satisfies the efficiency threshold, indicating inefficient operation. In a conveyor system, the efficiency metric may be based on the throughput estimate of the material transported to the expected material movement based on the power consumption of the conveyor motor. If the conveyor motor is using more power than expected but the throughput remains lower than expected, the controller 201 may determine that the efficiency metric satisfies the efficiency threshold, indicating inefficient operation.

The controller 201 may cause various operations in response to a determination that the machine 100 is operating inefficiently. In some embodiments, the controller 201 may output to an operator interface an indication that the machine 100 is operating inefficiently, in response to a determination that the machine 100 is operating inefficiently.

The controller 201 may cause, based on determining that the machine 100 is operating inefficiently, an adjustment to the machine 100 to operate the machine 100 more efficiently. The controller 201 may cause the adjustment by transmitting a control signal to one or more elements of the machine 100 to control one or more operating parameters thereof. For example, the controller 201 can transmit the control signal that includes an instruction to increase or decrease the one or more operating parameters by a particular amount, to the motor 230, the motor inverter 220, a variable frequency driver (VFD) of the motor 230, or any system that can control the machine 100.

In some examples, based on determining that the machine 100 is operating inefficiently, the controller 201 can cause the adjustment to various operating parameters of the machine 100 (e.g., operating parameters of the throughput-affecting component 240, the component 250, etc.), for example, by transmitting the control signal to the motor 230 (and/or the motor inverter 220, VFD, or any control system that controls the operating parameters of the machine 100) to increase or decrease the operating parameters of the machine 100. For example, the controller 201 may cause the adjustments to a travel speed of the machine 100, a pump speed and/or pressure of a pump that controls a hydraulic system of the machine 100, an electric motor speed, a pad thickness setting, a cut depth setting, etc. In some examples, based on determining that the machine 100 is operating inefficiently, the controller 201 can cause the adjustment to the speed of the motor 230 (and/or the motor inverter 220, VFD, or any control system that controls the speed of the motor 230) that controls the throughput-affecting component 240, for example, by transmitting the control signal to increase or decrease an operating parameter of the throughput-affecting component 240 (e.g., an auger speed, a conveyor speed, a milling drum speed, etc.). The controller 201 may determine the amount or the type of adjustment using the energy data, the throughput estimate, and/or the efficiency metric. Moreover, the controller 201 can determine which element of the machine 100 is to be adjusted, which operating parameter of the element is to be adjusted, etc., based on the energy data, the throughput estimate, the efficiency metric, and/or a type of the throughput-affecting component 240. In some embodiments, the controller 201 can determine the adjustment based on an ML model trained to determine an adjustment that would improve the efficiency of the machine 100 based on an input of the energy data, the sensor data, the throughput estimate, the efficiency metric, and/or the type of the throughput-affecting component 240.

As the adjustment to the travel speed and/or the operating parameter (e.g., of the throughput-affecting component 240) can control and/or optimize an amount of energy consumed in traveling and an amount of energy to operate the throughput-affecting component 240, the battery 212 may conserve more energy and extend the machine's operating time before recharging. Furthermore, the controller 201 can improve overall efficiency while preventing unnecessary power drain.

The control system 200 can be further configured to detect a malfunction or other fault in an element of the machine 100. Here, the controller 201 may compare the energy data and the throughput estimate to historical energy data and a historical throughput estimate. The controller 201 can identify deviations or anomalies, such as whether the energy data and the throughput estimate deviate significantly from historical trends. In response to a detection of such deviations, the controller 201 can identify potential faults or system malfunctions. For example, the controller 201 may determine, based on a deviation of the historical energy data and the historical throughput estimate from the energy data and the throughput estimate, respectively, that the throughput-affecting component 240 is faulty. As another example, the controller 201 may identify a malfunctioning component based on a determination that the machine 100 previously operated at a certain speed and under specific conditions while maintaining a certain level of efficiency, but now exhibits reduced efficiency despite identical conditions. The controller 201 may transmit an indication that the throughput-affecting component 240, or another malfunctioning component, is faulty based on determining a fault or malfunction. This provides several advantages by enabling proactive maintenance and minimizing downtime, allowing operators to address the problem before it leads to system failure and/or continued operation under inefficient conditions. Therefore, this can help improve operational efficiency, reduce maintenance costs, and prevent unexpected disruptions in production.

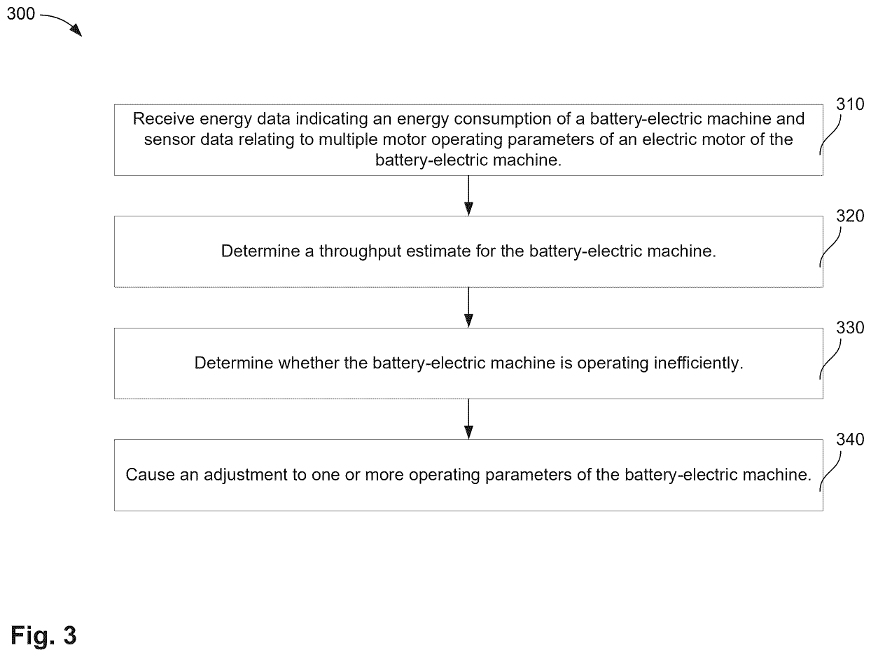

FIG. 3 is a flowchart of an example method 300. One or more steps of the method 300 may be performed by one or more controllers (e.g., the controller 201). Additionally, or alternatively, one or more steps of the method 300 may be performed by another device or a group of devices separate from or including the controller(s), such as another device or component that is internal or external to the machine 100.

At step 310, the method 300 may include receiving (e.g., using the controller 201) energy data indicating an energy consumption of a battery-electric machine (e.g., the machine 100) and sensor data relating to multiple motor operating parameters of an electric motor (e.g., the motor 230) of the battery-electric machine.

At step 320, the method 300 may include determining (e.g., using the controller 201 and/or using the sensor data), a throughput estimate for the battery-electric machine. In some embodiments, the method 300 may include determining (e.g., using the controller 201) a speed of a motor (e.g., the motor 230) and at least one of a torque or a power of the motor.

At step 330, the method 300 may include determining (e.g., using the controller 201, the energy data, and/or the throughput estimate), whether the battery-electric machine is operating inefficiently. In some embodiments, the method 300 may include determining (e.g., using the controller 201) whether an efficiency metric based on the energy data and the throughput estimate satisfies a threshold.

At step 340, the method 300 may include causing (e.g., using the controller 201), based on determining that the battery-electric machine is operating inefficiently, an adjustment to one or more operating parameters of the battery-electric machine.

In some embodiments, the method 300 may include determining (e.g., using the controller 201) the adjustment using the energy data and the throughput estimate. In some embodiments, the method 300 may include comparing (e.g., using the controller 201) the energy data and the throughput estimate to historical energy data and a historical throughput estimate, determining (e.g., using the controller 201), based on a deviation of the historical energy data and the historical throughput estimate from the energy data and the throughput estimate, respectively, that a throughput-affecting component (e.g., the throughput-affecting component 240) is faulty, and/or transmitting (e.g., using the controller 201) an indication that the throughput-affecting component is faulty based on determining that the throughput-affecting component is faulty.

Although FIG. 3 shows example steps of the method 300, in some implementations, the method 300 may include additional steps, fewer steps, different steps, or differently arranged steps than those depicted in FIG. 3. Additionally, or alternatively, two or more of the steps of the method 300 may be performed in parallel.

### INDUSTRIAL APPLICABILITY

The control system 200 described herein may be used with any machine that includes the throughput-affecting component 240 (e.g., an auger, a conveyor, a milling drum, or the like). For example, the control system 200 may be used in a paver, a cold planer, a milling machine, a compactor, or another type of work machine that performs road surfacing operations, earth moving operations, or the like. In particular, the control system 200 may be used in a battery-electric machine that operates at a worksite or other setting to improve efficiency and battery life. Unlike diesel-powered machines that can operate for extended periods with refueling, electric machines often require frequent recharging, leading to increased downtime and reduced overall productivity. In one example, in a paver involved in a paving process, adjusting operational parameters in response to a detected inefficiency is useful for optimizing the overall performance of the paver.

The control system 200 enhances machine efficiency, extends operating time, and optimizes performance. The control system 200 can determine whether the machine 100 is operating inefficiently by analyzing an efficiency metric based on energy data, sensor data, and other relevant parameters. Upon detecting inefficiencies, the control system 200 can dynamically adjust operating parameters, such as a travel speed or a motor speed, to improve energy efficiency and optimize throughput. This provides a simple solution for increasing machine performance and reducing downtimes using sensor data readily available from the machine 100 and thus without the need for additional equipment on the machine 100.

Additionally, the control system 200 is capable of detecting malfunctions by comparing energy data and throughput estimates to historical data. If deviations are detected, the control system 200 can identify potential faults in components such as the throughput-affecting component 240. This maintenance capability helps minimize downtime by allowing issues to be addressed before leading to complete system failure or prolonged inefficient operation. As a result, the control system 200 can contribute to improved operational efficiency, reduced maintenance costs, and fewer unexpected disruptions in production.

The foregoing describes only some embodiments, and alterations, modifications, additions and/or changes can be made thereto without departing from the scope and spirit of the disclosed embodiments, the embodiments being illustrative and not restrictive. Furthermore, implementations are not limited to the disclosed embodiments, and may cover various modifications and equivalent arrangements included within the spirit and scope of the disclosed embodiments. Also, the various embodiments described above may be implemented in conjunction with other embodiments, for example, aspects of one embodiment may be combined with aspects of another embodiment to realize yet other embodiments. Further, each independent feature or component of any given assembly or process may constitute an additional embodiment. As used herein, the singular forms of “a,” “an,” and “the” include plural referents unless the context clearly dictates otherwise. In addition, as used herein, the term “or” means “and/or” unless the context clearly dictates otherwise.

When “a controller” or “one or more controllers” is described or claimed (within a single claim or across multiple claims) as performing multiple operations or being configured to perform multiple operations, unless described or claimed otherwise (e.g., via the use of “first controller” and “second controller” or other language that differentiates controllers) this language is intended to cover a single controller performing or being configured to perform all of the operations, a group of controllers collectively performing or being configured to perform all of the operations, a first controller performing or being configured to perform a first operation and a second controller performing or being configured to perform a second operation, or any combination of controllers performing or being configured to perform the operations.

What is claimed is:

1. A control system for a battery-electric machine, comprising:
a battery monitoring system for one or more batteries of the battery-electric machine;
one or more sensors configured to measure multiple motor operating parameters of an electric motor that operates a throughput-affecting component of the battery-electric machine; and
a controller configured to:
receive, from the battery monitoring system, energy data indicating an energy consumption of the battery-electric machine;
receive, from the one or more sensors, sensor data relating to the multiple motor operating parameters;
determine, using the sensor data, a throughput estimate for the battery-electric machine;
determine, using the energy data and the throughput estimate, whether the battery-electric machine is operating inefficiently; and
cause, based on determining that the battery-electric machine is operating inefficiently, an adjustment to a travel speed of the battery-electric machine or a motor speed of the electric motor.

2. The control system of claim 1, wherein the controller is further configured to output to an operator interface an indication that the battery-electric machine is operating inefficiently, in response to a determination that the battery-electric machine is operating inefficiently.

3. The control system of claim 1, wherein the multiple motor operating parameters include at least two of a current, a voltage, or a speed of the electric motor.

4. The control system of claim 1, wherein the controller is further configured to:
determine a speed of the electric motor and at least one of a torque or a power of the electric motor; and
determine the throughput estimate based on the speed of the electric motor and at least one of the torque or the power of the electric motor.

5. The control system of claim 1, wherein the controller is further configured to:
determine, based on a first machine learning (ML) model, whether the battery-electric machine is operating inefficiently, wherein the first ML model is trained to output an efficiency indication based at least on a first input of the energy data, the sensor data, and the throughput estimate; or
determine, based on a second ML model, the adjustment, wherein the second ML model is trained to output adjustment information based at least on a second input of the energy data, the sensor data, the throughput estimate, and a type of the throughput-affecting component.

6. The control system of claim 1, wherein the throughput-affecting component is an auger, a conveyor, or a milling drum.

7. The control system of claim 1, wherein the energy data includes at least one of a current value, a voltage value, or a total energy value.

8. The control system of claim 1, wherein the controller, to determine whether the battery-electric machine is operating inefficiently, is configured to determine whether an efficiency metric based on the energy data and the throughput estimate satisfies a threshold.

9. The control system of claim 1, wherein the controller is further configured to determine the adjustment using the energy data and the throughput estimate.

10. The control system of claim 1, wherein the battery-electric machine is a paver or a cold planer.

11. A method, comprising:
receiving, by a controller, energy data indicating an energy consumption of a battery-electric machine and sensor data relating to multiple motor operating parameters of an electric motor of the battery-electric machine;
determining, by the controller and using the sensor data, a throughput estimate for the battery-electric machine;
determining, by the controller and using the energy data and the throughput estimate, whether the battery-electric machine is operating inefficiently; and
causing, by the controller and based on determining that the battery-electric machine is operating inefficiently, an adjustment to one or more operating parameters of the battery-electric machine.

12. The method of claim 11, further comprising:
comparing the energy data and the throughput estimate to historical energy data and a historical throughput estimate;
determining, based on a deviation of the historical energy data and the historical throughput estimate from the energy data and the throughput estimate, respectively, that a throughput-affecting component is faulty; and
transmitting an indication that the throughput-affecting component is faulty based on determining that the throughput-affecting component is faulty.

13. The method of claim 11, further comprising determining a speed of a throughput-affecting component that is operated by the electric motor and at least one of a torque or a power of the throughput-affecting component.

14. The method of claim 11, wherein determining the throughput estimate comprises determining the throughput estimate based on a speed of a throughput-affecting component that is operated by the electric motor and at least one of a torque or a power of the throughput-affecting component.

15. The method of claim 11, wherein determining whether the battery-electric machine is operating inefficiently comprises determining whether an efficiency metric based on the energy data and the throughput estimate satisfies a threshold.

16. The method of claim 11, further comprising determining the adjustment using the energy data and the throughput estimate.

17. The method of claim 11, wherein the one or more operating parameters include at least one of a machine travel speed, an electric motor speed, a hydraulic pump speed, a pad thickness setting, or a cut depth setting.

18. A battery-electric machine, comprising:
a battery monitoring system for one or more batteries of the battery-electric machine;
a throughput-affecting component that contributes to a throughput of a work operation of the battery-electric machine;
an electric motor configured to operate the throughput-affecting component;
a motor inverter configured to control the electric motor;
one or more sensors configured to measure one or more operating parameters of the electric motor; and
a controller configured to:
receive, from the battery monitoring system, energy data indicating an energy consumption of the battery-electric machine;
receive, from the motor inverter and the one or more sensors, sensor data relating to multiple motor operating parameters of the electric motor;
determine, using the sensor data, a throughput estimate for the battery-electric machine;
determine, using the energy data and the throughput estimate, an efficiency metric indicative of whether the battery-electric machine is operating inefficiently; and
cause, based on the efficiency metric, an adjustment to a travel speed of the battery-electric machine or a motor speed of the electric motor.

19. The battery-electric machine of claim 18, wherein the controller is further configured to:
compare the energy data and the throughput estimate to historical energy data and a historical throughput estimate;
determine, based on a deviation of the historical energy data and the historical throughput estimate from the energy data and the throughput estimate, respectively, that the throughput-affecting component is faulty; and
transmit an indication that the throughput-affecting component is faulty based on determining that the throughput-affecting component is faulty.

20. The battery-electric machine of claim 18, wherein the controller is further configured to transmit the energy data and the sensor data to a remotely-located system for fleet-level efficiency monitoring.
